(19) United States
(12) Patent Application Publication
(10) Pub. No.: US 2010/0020274 A1
(43) Pub. Date: Jan. 28, 2010

(54) COLORANT, COLOR FILTER, LCD DEVICE, COMPOSITION AND METHOD FOR PREPARING THE SAME

(75) Inventors: Zhuo ZHANG, Beijing (CN); Xuan HE, Beijing (CN); Lin LI, Beijing (CN); Jiuxia YANG, Beijing (CN); Jisheng ZHAO, Beijing (CN)

Correspondence Address: J C PATENTS, 4 VENTURE, SUITE 250, IRVINE, CA, 92618, US

(73) Assignee: BOE TECHNOLOGY GROUP CO.,LTD, Beijing (CN)

(21) Appl. No.: 12/505,298

(22) Filed: Jul. 17, 2009

(30) Foreign Application Priority Data
Jul. 24, 2008 (CN) 200810117125.7

(51) Int. Cl. G02F 1/1335; C08L 33/02; G03F 7/004; G02B 5/22

(52) U.S. Cl. 349/106; 524/539; 524/556; 430/286.1; 359/885

(57) ABSTRACT

The present invention relates to a colorant, a color filter, LCD device, a composition and a method for preparing the same. The colorant covers pigment particles by using the acrylic acid polymer having an acid value greater than 20 mgKOH/g and containing aromatic group so as to greatly improve the stability while improving the dispersion ability of the pigment particles. By the above colorant, the photosensitive resin composition ensures that the developing performance is basically not influenced so that the photosensitive resin composition can meet the need of high transmissivity, high color purity, and high contrast for a color filter. A pattern on the color filter is formed by using the photosensitive resin composition having high dispersion stability and developing performance so as to greatly improve transmissivity, color purity, and contrast. An LCD device uses the color filter with high transmissivity, high color purity, and high contrast so as to greatly improve the display effect of color images.

### CROSS-REFERENCE TO RELATED APPLICATIONS

This application claims priority to Chinese Patent Application No. 200810117125.7, filed on Jul. 24, 2008, entitled “Colorant, Color Filter, LCD Device, Composition and Method for Preparing the Same”, which is incorporated herein by reference in its entirety.

### FIELD OF THE TECHNOLOGY

The present invention relates to a color filter, particularly to a colorant, a color filter, a liquid crystal display (LCD) device, a photosensitive resin composition which can improve color display effect of the LCD device, and a method for preparing the same.

### BACKGROUND

A color filter is critical for realizing color display for an LCD. Methods for preparing a color filter include: staining process, pigment dispersion process, printing process, electroplating process, ink-jet process, etc. The pigment dispersion process is mainly used for preparing the color filter as it has advantage in terms of color feature and quality. The pigment dispersion process for preparing the color filter is mainly implemented by a series of operations such as coating photoresist onto a substrate, exposing, developing so as to achieve the aim of patterning and obtaining a color filter.

The photoresist is a photosensitive resin composition consisting of colorant, alkali-soluble resin, multi-functional group photosensitive resin, initiator and solvent, referring to documents such as Japanese patent applications with Publication No. JP 1-152449, JP 9-311210, JP 2-144502, JP 3-53201 and Chinese patent applications with Grant Bulletin No. CN 1220114C, CN 1277132C and Publication No. CN 1584637A.

With increasingly high demand for LCD, a higher demand is proposed that the color filter needs to possess high transmissivity, high color purity, and high contrast. In order to achieve such subject, it is critical for a photosensitive resin composition to possess favorable dispersion stability.

The photosensitive resin composition is obtained by mixing colorant obtained by pigment refining and dispersing with alkali-soluble resin, multi-functional group photosensitive resin and solvent.

In prior art, during refining pigment, pigment particles tends to agglomerate as the surface area increases, which decreases stability and increases viscosity. In order to increase stability and decrease viscosity during refining pigment, it is needed to add surface active agent, high molecular dispersant, or dispersion resin during refining pigment. As recorded in Chinese patent application with Publication No. CN 1677139A, acrylic acid copolymer with an ammonia value greater than 0 and an acid value being 0 is used as the dispersion resin.

Deficiencies of the prior art lie in that, type and using amount of the dispersant or the dispersion resin have considerate impact on stability of the pigment disperse system in the colorant, which results in bad disperse stability of the colorant; And the developing performance of the photosensitive resin composition decrease considerably with increase of the using amount of the colorant. For example, when an acrylic acid copolymer with an ammonia value greater than 0 and an acid value being 0 is used as colorant for preparing dispersion resin to be added into the alkali-soluble resin, the alkali-soluble resin is diluted with increase of the using amount of the colorant, which results in decrease of concentration and decrease of developing performance of the photosensitive resin composition. Besides, the acrylic acid copolymer with an ammonia value greater than 0 and an acid value being 0 used as the dispersion resin reduces available choice of dispersion resins, which greatly limits application fields of the colorant prepared.

### SUMMARY

A subject of the present invention is to provide a colorant, a color filter, a composition and a method for preparing the same so as to meet the need of high transmissivity, high color purity, and high contrast of the color filter.

Another subject of present invention is to provide an LCD device so as to improve color display effect of the LCD device.

In order to achieve the above subject, an embodiment of the present invention provides a colorant, including a pigment, a dispersant or a dispersion resin, a solvent and at least one kind of acrylic acid polymer. The acrylic acid polymer is adapted to be mixed with the dispersant or dispersion resin by the solvent for dispersing and stabilizing the pigment. The acrylic acid polymer has an acid value greater than 20 mgKOH/g and contains aromatic group.

The colorant in the present solution covers pigment particles by using the acrylic acid polymer having an acid value greater than 20 mgKOH/g and containing aromatic group so as to greatly improve the stability while improving the dispersion ability of the pigment particles.

An embodiment of the present invention further provides a photosensitive resin composition, including a colorant, a multi-functional group monomer or a combination of a multi-functional group monomer and a mono-functional group monomer, an optical initiator, and a solvent. The colorant is mixed together with the multi-functional group monomer or the combination of the multi-functional group monomer and the mono-functional group monomer, the optical initiator, and the solvent.

An embodiment of the present invention further provides a method for preparing the above photosensitive resin composition. The method includes the following steps:
dissolving at least one kind of the acrylic acid polymer into solvent, wherein the acrylic acid polymer has an acid value greater than 20 mgKOH/g and contains aromatic group;
adding the pigment into solution in which at least one kind of acrylic acid polymer is dissolved, and stirring;
adding the dispersant or dispersion resin, stirring, and refining; and
adding the multi-functional group monomer or combination of multi-functional group monomer and mono-functional group monomer, optical initiator, and solvent.

The photosensitive resin composition in the present solution disperses the pigment particles by using the acrylic acid polymer having an acid value greater than 20 mgKOH/g in the colorant so that the using amount of the colorant almost has no influence on the concentration of the alkali-soluble resin and the developing performance of the photosensitive resin composition is basically not influenced. Therefore, the photosensitive resin composition can meet the need of high transmissivity, high color purity, and high contrast for the color filter.

An embodiment of the present invention further provides a color filter, including a substrate. The substrate is provided with a pattern formed by the photosensitive resin composition in the above solution.

The pattern on the color filter of the present solution is formed by using the photosensitive resin composition having high dispersion stability and developing performance so as to greatly improve transmissivity, color purity, and contrast.

In order to achieve the above second subject, an embodiment of the present invention provides an LCD device, including a liquid crystal layer. The above color filter is disposed over the liquid crystal layer.

The LCD device of the present solution uses the color filter with high transmissivity, high color purity, and high contrast so as to greatly improve the display effect of color images.

### BRIEF DESCRIPTION OF THE DRAWINGS

FIG. 1 is a flowchart of the embodiment of the method for preparing the photosensitive resin composition in accordance with the present invention.

### DETAILED DESCRIPTION

The present invention is described in detail below through embodiments accompanied with drawings.

### Embodiment of Colorant

The colorant in the present embodiment may include pigment, dispersant or dispersion resin, solvent, and at least one acrylic acid polymer. The acrylic acid polymer may contain or not contain a methyl, which is used to disperse and stabilize the pigment together by mixing with the dispersant in the solvent.

The acrylic acid polymer has an acid value greater than 20 mgKOH/g and contains an aromatic group.

In the present embodiment, the colorant covers the pigment particles by using the acrylic acid polymer with an acid value greater than 20 mgKOH/g and containing an aromatic group so as to greatly improve the stability while improving the dispersion ability of the pigment particles.

The ingredient in the above embodiment will be explained in detail as follows:

I. Pigment

In the above embodiment, the pigment may be organic pigment or inorganic pigment.

The organic pigment may be a compound whose classification in a pigment index (C.I.; The Society of Dyers and Colourists) is pigment, which may be specifically a substance with the following pigment index (C.I.) number:

C.I. pigment yellow 12, C.I. pigment yellow 13, C.I. pigment yellow 14, C.I. pigment yellow 17, C.I. pigment yellow 20, C.I. pigment yellow 24, C.I. pigment yellow 31, C.I. pigment yellow 55, C.I. pigment yellow 83, C.I. pigment yellow 93, C.I. pigment yellow 109, C.I. pigment yellow 110, C.I. pigment yellow 138, C.I. pigment yellow 139, C.I. pigment yellow 150, C.I. pigment yellow 153, C.I. pigment yellow 154, C.I. pigment yellow 155, C.I. pigment yellow 166, C.I. pigment yellow 168, and C.I. pigment yellow 211;

C.I. pigment orange 36, C.I. pigment orange 43, C.I. pigment orange 51, C.I. pigment orange 61, and C.I. pigment orange 71;

C.I. pigment red 9, C.I. pigment red 97, C.I. pigment red 122, C.I. pigment red 123, C.I. pigment red 149, C.I. pigment red 168, C.I. pigment red 176, C.I. pigment red 177, C.I. pigment red 180, C.I. pigment red 185, C.I. pigment red 207, C.I. pigment red 208, C.I. pigment red 209, C.I. pigment red 215, C.I. pigment red 224, C.I. pigment red 242, C.I. pigment red 243, and C.I. pigment red 254;

C.I. pigment purple 19, C.I. pigment purple 23, and C.I. pigment purple 29;

C.I. pigment blue 15, C.I. pigment blue 60, C.I. pigment blue 15:3, C.I. pigment blue 15:4, and C.I. pigment blue 15:6;

C.I. pigment green 7, C.I. pigment green 36, C.I. pigment green 136, and C.I. pigment green 210;

C.I. pigment brown 23, and C.I. pigment brown 25;

These organic pigments may be used separately or mixed with two or more kinds thereof; alternatively, the organic pigment may also be used after being refined by adopting a re-crystallization process, a re-precipitation process, a solvent washing process, a sublimation process, and a vacuum heating process, or a combination of the above processes.

The inorganic pigment may be titanium dioxide, barium sulfate, calcium carbonate, zinc white, lead sulfate, yellow lead, zinc yellow, iron oxide red (red iron oxide (III)), cadmium red, ultramarine, deep blue, chromium oxide green, cobalt green, brown soil, titanium black, synthetic iron black, and carbon black, etc.

These inorganic pigments may be used separately or mixed with two or more kinds thereof.

In addition, the above pigment may also be used together with dye or natural pigment in the colorant of the above embodiment.

II. Acrylic Acid Polymer

The acrylic acid polymer has an acid value greater than 20 mgKOH/g and an ammonia value without limit, and contains an aromatic group which preferably is a benzene ring. The acrylic acid polymer and other dispersant or dispersion resin stabilize and refine the pigment particles together.

The acrylic acid polymer is a copolymer which is formed by polymerizing an unsaturated monomer having an aromatic function group with other polymerizable monomer.

First) Unsaturated Monomer Having an Aromatic Function Group

The above monomer having the aromatic function group may include:

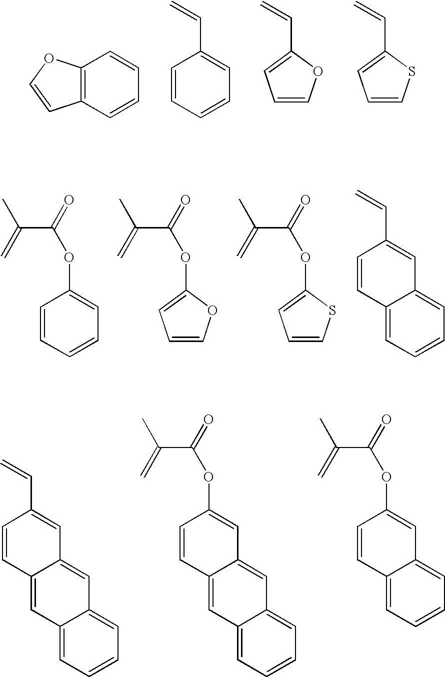

and α-methyl styrene, o-vinyltoluene, p-vinyltoluene, m-vinyltoluene, methyl acrylic acid phenyl ester, acrylic acid phenyl ester, methyl acrylic acid benzyl ester, acrylic acid benzyl ester, methyl acrylic acid phenethyl ester, acrylic acid phenethyl ester, methyl acrylic acid phenyl propyl ester, and acrylic acid phenyl propyl ester, etc.

The above monomer having the aromatic function group may preferably be styrene, and methyl acrylic acid benzyl ester. The acrylic acid polymer may be polymerized by using any one or any combination in the above embodiment of the unsaturated monomer.

Second) Other Polymerizable Monomer

1) Unsaturated Monomer Containing Carboxylic Acid (Anhydride) Group

The above other polymerizable monomer at least include one unsaturated monomer containing a carboxylic acid (anhydride) group.

It is applicable as long as the unsaturated monomer containing carboxylic acid (anhydride) group can be polymerized with the above monomer containing an aromatic functional group, which may be an unsaturated monoacid such as acrylic acid, methyl acrylic acid, butenoic acid, α-chloracrylic acid, ethyl acrylic acid, and cinnamic acid; an unsaturated dibasic carboxylic acid (anhydride) such as maleic acid, maleic acid anhydride, fumaric acid, itaconic acid, itaconic acid anhydride, citraconic acid, citraconic acid anhydride; an unsaturated polyvalent carboxylic acid (anhydride) with more than trivalence; and a low polymer containing carboxylic acid (anhydride) group.

The above unsaturated monomer containing a carboxylic acid (anhydride) group may preferably acrylic acid, methyl acrylic acid, and maleic acid anhydride. The acrylic acid polymer may be polymerized by adopting any one or any combination of the above unsaturated monomer containing a carboxylic acid (anhydride) group.

2) Monomer Not Containing Carboxylic Acid (Anhydride) Group

The above other polymerizable monomer, besides the above unsaturated monomer containing a carboxylic acid (anhydride) group, may also include the following polymerizable monomer not containing a carboxylic acid (anhydride) group:

Unsaturated carboxylic acid ester such as acrylic acid methyl ester, methyl acrylic acid methyl ester, acrylic acid ethyl ester, methyl acrylic acid ethyl ester, acrylic acid normal propyl ester, methyl acrylic acid normal propyl ester, acrylic acid isopropyl ester, methyl acrylic acid isopropyl ester, acrylic acid normal butyl ester, methyl acrylic acid normal butyl ester, acrylic acid isobutyl ester, methyl acrylic acid isobutyl ester, acrylic acid tert-butyl ester, methyl acrylic acid tert-butyl ester, acrylic acid 2-hydroxyl ethyl ester, methyl acrylic acid 2-hydroxyl ethyl ester, acrylic acid 2-hydroxyl propyl ester, methyl acrylic acid 2-hydroxyl propyl ester, acrylic acid 3-hydroxyl propyl ester, methyl acrylic acid 3-hydroxyl propyl ester, acrylic acid 2-hydroxyl butyl ester, methyl acrylic acid 2-hydroxyl butyl ester, acrylic acid 3-hydroxyl butyl ester, methyl acrylic acid 3-hydroxyl butyl ester, acrylic acid 4-hydroxyl butyl ester, methyl acrylic acid 4-hydroxyl butyl ester, acrylic acid allyl ester, methyl acrylic acid allyl ester, acrylic acid triethylene glycol methoxyl ester, methyl acrylic acid triethylene glycol methoxyl ester, methyl acrylic acid dodecyl ester, methyl acrylic acid myristyl ester, methyl acrylic acid cetyl ester, methyl acrylic acid octadecyl ester, methyl acrylic acid eicosyl ester, and methyl acrylic acid docosyl ester;

Unsaturated carboxylic acid aminoalkyl ester such as acrylic acid 2-aminoa ethyl ester, methyl acrylic acid 2-aminoa ethyl ester, acrylic acid 2-aminoa propyl ester, methyl acrylic acid 2-aminoa propyl ester, acrylic acid 3-aminoa propyl ester, and methyl acrylic acid 3-aminoa propyl ester;

Unsaturated carboxylic acid epoxypropyl ester such as acrylic acid epoxypropyl ester, and methyl acrylic acid epoxypropyl ester;

Carboxylic acid vinyl ester such as acetic acid vinyl ester, propionic acid vinyl ester, butanoic acid vinyl ester, and benzoic acid vinyl ester;

Unsaturated ether such as vinyl methyl ether, vinyl ethyl ether, allyl epoxypropyl ether, and methallyl epoxypropyl ether;

Vinyl cyanide compound such as acrylonitrile, methyl acrylonitrile, a-chloro acrylonitrile, and vinylidene cyanide;

Unsaturated thiamine such as propenyl thiamine, methyl propenyl thiamine, a-chloro propenyl thiamine, N-ethoxyl propenyl thiamine, and N-ethoxyl methyl propenyl thiamine; and

Fatty conjugated diene such as 1, 2-butadiene, ethyl propenyl, and chloropropene.

The above polymerizable monomer not containing a carboxylic acid (anhydride) group is preferably acrylic acid methyl ester, methyl acrylic acid methyl ester, acrylic acid 2-ethoxyl ester, methyl acrylic acid 2-ethoxyl ester, acrylic acid butyl ester, or methyl acrylic acid butyl ester. The acrylic acid polymer may be polymerized by using any one or any combination of the above esters and the unsaturated monomer containing a carboxylic acid (anhydride) group as other polymerizable monomer, and polymerized with the monomer having an aromatic function group to form the acrylic acid polymer.

Supposedly, total amount of all the monomer of the acrylic acid polymer used for polymerizing is 100 parts by weight (pbw). During polymerizing the acrylic acid polymer, the using amount of monomer having aromatic functional groups preferably is 20-90 pbw, and more preferably is 45-70 pbw. The using amount of other polymerizable monomer is preferably 10-80 pbw, in which the using amount of monomer having carboxylic acid (anhydride) groups shall be greater than 1, preferably is 5-40 pbw, and more preferably is 10-30 pbw.

The method for polymerizing the acrylic acid polymer and the initiator used are not limited. The method preferably is a solution free radical polymerizing method, and the initiator preferably is azo compound.

The weight-average molecular weight of the acrylic acid polymer is commonly 3000 to 400000, preferably is 5000 to 50000. The weight-average molecular weight of the acrylic acid polymer may be measured by a gel permeation chromatography (GPC, solvent is THF, standardized by polystyrene).

The acrylic acid polymer may also be commercially available for example Joncryl 611 of BASF.

The colorant of the above embodiment may include any one or any combination of the above acrylic acid polymer.

The above acrylic acid polymer is used together with the other dispersant or other dispersion resin, and can be added before adding pigment. The using ratio of the acrylic acid polymer is 1-200 pbw based on 100 pbw of the pigment, preferably is 30-100 pbw.

III. Dispersant or Dispersion Resin

Other dispersant or dispersion resin which can be used together with the acrylic acid polymer are not specifically limited, which may be poly(ethylene oxide)alkyl ether such as poly(ethylene oxide)dodecyl ether, poly(ethylene oxide)stearoyl ether, and poly(ethylene oxide)oil ether; poly(ethylene oxide)alkyl phenyl ether such as poly(ethylene oxide)octyl phenyl ether, and poly(ethylene oxide)nonyl phenyl ether; polyethylene glycol diester such as polyethylene glycol dilauric acid ester, and polyethylene glycol distearic acid ester; sorbitan fatty acid ester; fatty acid modified polyester; tert-amine modified polyamine formic acid ester; and polyethyleneimine. Besides, it may further include the following commodities: KP (made by ShinEtsu Chemical Industry), SF-8427 (made by Toray Dow Corning Silicon), Polyflow (made by KYOEI Oil and Fat Chemical Industry), F-Top (made by Tochem Products Co., Ltd.), Megafac (made by DIC Chemical Industry), Flrorade (made by SUMITOMO 3M), Asahi Guard, Surflon (made by AGC), DisperBYK-101, DisperBYK-103, DisperBYK-107, DisperBYK-110, DisperBYK-111, DisperBYK-115, DisperBYK-130, DisperBYK-160, DisperBYK-161, DisperBYK-162, DisperBYK-163, DisperBYK-164, DisperBYK-165, DisperBYK-166, DisperBYK-166, DisperBYK-170 (BYK, German BYK Chemistry Co., Ltd.), Solsperse 5000, Solsperse 12000, Solsperse 13240, Solsperse 13940, Solsperse 17000, Solsperse 20000, Solsperse 22000, Solsperse 24000, Solsperse 24000GR, Solsperse 26000, Solsperse 27000, Solsperse 28000 (Avecia, Japan Fujifilm Corporation), EFKA46, EFKA47, EFKA48, EFKA745, EFKA4047, EFKA4046, EFKA4080, EFKA4400, EFKA4401, EFKA1101, EFKA4403, EFKA4540, EFKA4550, EFKA6750, EFKA LP4008, EFKA LP4009, EFKA LP4010, EFKA LP4015, EFKA LP4050, EFKA LP4055, EFKA LP4560, EFKA LP4800, EFKA Ploymer400, EFKA Ploymer401, EFKA Ploymer402, EFKA Ploymer403, EFKA Ploymer450, EFKA Ploymer451, EFKA Ploymer453 (EFKA, Dutch EDKA Additives Corporation).

The dispersant or dispersion resin which can be used together with the acrylic acid polymer may be any one or any combination of the above. Based on 100 pbw of the acrylic acid polymer (counted based on solid components), the using amount of the dispersant or dispersion resin is 1-300 pbw, and preferably is 20-80 pbw.

IV. Solvent

Any substance can be used as the solvent as long as it enables the acrylic acid polymer to be dispersed or dissolved with the dispersant or dispersion resin and additives ingredient used together therewith, and not react with these ingredients. The solvent may be as follows:

Alcohol such as methanol, ethanol, benzyl alcohol;

(Poly)alkyl glycol monoalkyl ether such as glycol monomethyl ether, glycol monoethyl ether, glycol mononormalpropyl ether, glycol mononormalbutyl ether, diglycol monomethyl ether, diglycol monoethyl ether, diglycol mononormalpropyl ether, diglycol mononormalbutyl ether, triglycol monomethylether, triglycol monoethyl ether, propylene glycol monomethyl ether, propylene glycol monoethyl ether, dipropylene glycol monomethyl ether, dipropylene glycol monoethyl ether, dipropylene glycol mononormalpropyl ether, dipropylene glycol mononormalbutyl ether, tripropylene glycol monomethyl ether, and tripropylene glycol monoethyl ether;

(Poly)alkyl glycol monoalkyl ether acetic acid ester such as glycol monomethyl ether acetic acid ester, glycol monoethyl ether acetic acid ester, glycol mononormalpropyl ether acetic acid ester, glycol mononormalbutyl ether acetic acid ester, diglycol monomethyl ether acetic acid ester, diglycol monoethyl ether acetic acid ester, diglycol mononormalpropyl ether acetic acid ester, diglycol mononormalbutyl ether acetic acid ester, propylene glycol monomethyl ether acetic acid ester, propylene glycol monoethyl ether acetic acid ester, and 3-methoxy butyl acetic acid ester;

Other ether such as diglycol dimethylether, diglycol methyl ethyl ether, diglycol diethyl ether, and tetrahydrofuran;

Ketone such as methyl ethyl ketone, cyclohexanone, 2-heptanone, 3-heptanone, diacetone alcohol (4-hydroxyl-4-methyl pentane-2-ketone), and 4-hydroxyl-4-methyl hexane-2-ketone;

Lactic acid alkyl ester such as lactic acid methyl ester, and lactic acid ethyl ester;

Other ester such as acetic acid ethyl ester, acetic acid normalpropyl ester, acetic acid isopropyl ester, acetic acid normalbutyl ester, acetic acid isobutyl ester, acetic acid normalamyl ester, acetic acid isoamyl ester, 3-methyl-3 methoxy butyl acetic acid ester, propionic acid normalbutyl ester, 3-methyl-3-methoxy butyl propionic acid ester, butanoic acid ethyl ester, butanoic acid normalpropyl ester, butanoic acid isopropyl ester, butanoic acid normalbutyl ester, hydroxyl acetic acid ethyl ester, ethoxy acetic acid ethyl ester, 3-methoxy propionic acid methyl ester, 3-methoxy propionic acid ethyl ester, 3-ethoxy propionic acid methyl ester, 3-ethoxy propionic acid ethyl ester, pyruvic acid methyl ester, pyruvic acid ethyl ester, pyruvic acid normalpropyl ester, acetyl acetic acid methyl ester, acetyl acetic acid ethyl ester, 2-hydroxyl-2-methyl propionic acid ethyl ester, and 2-hydroxyl-3 methyl butanoic acid methyl ester; and

Arene such as toluene, and xylene;

Acylamide such as N-methyl pyrrolidone, N,N-dimethyl formamide, and N,N-dimethyl acetamide.

During using, any one or any combination of the above solvent may be used.

In addition, the solvent may be any one or any combination of solvent with a high boiling point such as benzyl ethyl ether, dihexyl ether, acetonyl acetone, isophorone, hexanoic acid, octanoic acid, 1-octyl alcohol, 1-nonyl alcohol, acetic acid benzyl ester, benzoic acid ethyl ester, oxalic acid diethyl ester, maleic acid diethyl ester, γ-butyrolactone, vinyl carbonate, propenyl carbonate, and glycol monophenyl ether acetic acid ester, etc.

The above solvent may preferably be propylene glycol methyl ether acetic acid ester, 3-ethoxy propionic acid ethyl ester, and may also preferably be propylene glycol monomethyl ether so as to adjust the whole polarity of the solvent, improve stability of the colorant and lower its viscosity.

### Embodiment of the Photosensitive Resin Composition

The photosensitive resin composition in accordance with the embodiment of the present invention may include colorant, multi-functional group monomer or a combination of a multi-functional group monomer and a mono-functional group monomer, optical initiator and solvent. The colorant is any colorant provided in the above embodiment of colorant, and is mixed together with the multi-functional group monomer or a combination of the multi-functional group monomer and the mono-functional group monomer, optical initiator, and solvent.

The photosensitive resin composition in the present solution disperses the pigment particles by using the acrylic acid polymer in the colorant with a acid value greater than 20 mgKOH/g so as to prevent the using amount increase of the colorant from influencing the concentration of the alkali-soluble resin, and basically ensure the developing performance of the photosensitive resin composition not to be influenced. Compared with the prior art, the developing performance of the photosensitive resin composition in the present embodiment is greatly improved so as to obtain the photosensitive resin composition which can meet the need of high transmissivity, high color purity, high contrast for the color filter.

I. Alkali-Soluble Resin

The alkali-soluble resin and the acrylic acid polymer provided in the embodiment of colorant may be the same kind of resin, but may be different resins with different acid values, monomers and proportions, or molecular weights, etc.

The alkali-soluble resin is preferably resin with an acid value of 30-250 mgKOH/g, a weight-average molecular weight of 5000-40,000, and a hydroxyl value of 0.1-20 mgKOH/g.

Based on 100 pbw of pigment, the using amount of the alkali-soluble resin may be 0-120 pbw, preferably 10-80 pbw, more preferably 30-60 pbw.

II. Multi-functional Group Monomer or Combination of Multi-Functional Group Monomer and Mono-Functional Group Monomer

The multi-functional group monomer may be monomer having two or more polymerizable unsaturated bonds such as glycol di(methyl)acrylic acid ester, di(methyl)acrylic acid dicyclopentene ester, triglycol diacrylic acid ester, tetraglycol di(methyl)acrylic acid ester, tri(2-ethoxyl)isocyanic acid ester di(methyl)acrylic acid ester, tri(2-ethoxyl)isocyanic acid ester tri(methyl)acrylic acid ester, caprolactone-modified tri(2-ethoxyl)isocyanic acid ester tri(methyl)acrylic acid ester, tri(methyl)acrylic acid trihydroxymethyl propyl ester, expoxy ethane modified tri(methyl)acrylic acid trihydroxymethyl propyl ester, expoxy propane-modified tri(methyl)acrylic acid trihydroxymethyl propyl ester, triglycol di(methyl)acrylic acid ester, neopentyl glycol di(methyl)acrylic acid ester, 1,4-butylene glycol di(methyl)acrylic acid ester, 1,6-hexylene glycol di(methyl)acrylic acid ester, polyethylene glycol di(methyl)acrylic acid ester, dipentaerythritol hexa(methyl)acrylic acid ester, dipentaerythritol penta(methyl)acrylic acid ester, dipentaerythritol tetra(methyl)acrylic acid ester, caprolactone-modified dipentaerythritol hexa(methyl)acrylic acid ester, caprolactone-modified dipentaerythritol penta(methyl)acrylic acid ester, tetra(methyl)acrylic acid di-trihydroxymethyl propyl ester, expoxy ethane-modified diphenol A di(methyl)acrylic acid ester, expoxy propane-modified diphenol A di(methyl)acrylic acid ester, expoxy ethane-modified hydro diphenol A di(methyl)acrylic acid ester, expoxy propane-modified hydro diphenol A di(methyl)acrylic acid ester, expoxy propane-modified glycerol tripropionic acid ester, expoxy ethane-modified diphenol F di(methyl)acrylic acid ester, phenolic aldehyde polyglycidylether(methyl)acrylic acid ester.

The multi-functional group monomer may also be low polymer containing two or more polymerizable unsaturated bonds such as commercial EB264, EB270, EB1290 (Cytec Industries (Shanghai) Co. Ltd.); SB400, SB401, SB402, SB404, SB405 (America Sartomer Company Inc.); polyaminoa ester (methyl) acrylic acid ester oligomer, polyester(methyl)acrylic acid ester oligomer, expoxy(methyl)acrylic acid ester oligomer.

The multi-functional group monomer is preferably monomer containing three or more unsaturated bonds such as tri(methyl)acrylic acid trihydroxymethyl propyl ester, dipentaerythritol hexa(methyl)acrylic acid ester, dipentaerythritol penta(methyl)acrylic acid ester, dipentaerythritol tetra(methyl)acrylic acid ester, caprolactone-modified dipentaerythritol hexa(methyl)acrylic acid ester, caprolactone-modified dipentaerythritol penta(methyl)acrylic acid ester, tetra(methyl)acrylic acid di-trihydroxymethyl propyl ester.

The above multi-functional group monomer may be used separately or be used by mixing two or more thereof.

During preparing the photosensitive resin composition, based on 100 pbw of pigment, the using amount of multi-functional group monomer may 10-500 pbw, preferably 20-200 pbw.

The photosensitive resin composition may also be a combination of the multi-functional group monomer and the mono-functional group monomer. The mono-functional group monomer may be the unsaturated monomer containing a carboxyl provided in the embodiment of colorant used for being polymerized to acrylic acid polymer and the polymerizable unsaturated monomer.

During mixing the mono-functional group monomer and the multi-functional group monomer for use, one or more kinds of each may be added.

During preparing the photosensitive resin composition, based on 100 pbw of the using amount of multi-functional group, the using amount of the mono-functional group monomer may be 0-40 pbw, preferably 1-10 pbw.

III. Optical Initiator

The optical initiator may be any one or any combination of hypnone compound, diimidazole compound, triazine compound, benzoin compound, benzophenone compound, a-diketone compound, multi-core quinone compound, genicide compound, diazonium compound, which is preferably benzophenone compound, hypnone compound, and diimidazole compound, such as 4,4′-di(diethylamine) benzophenone, 2-benzyl-2-2dimethylamino-1-(4-morpholino phenyl)-butanone-1 (Ciba 369, 379), 2,2′-di(2-chlorophenyl)-4,4′,5,5′-tetraphenyl diimidazole.

During preparing the photosensitive resin composition, based on (D) multi-functional group monomer or a combination of the multi-functional group monomer and the mono-functional group monomer 100 pbw, the using amount of the optical initiator may be 0.01-100 pbw, preferably 3-70 pbw, more preferably 10-60 pbw. If the using amount of the optical initiator is less than 0.01 pbw, exposure solidification will be insufficient; and if the using amount goes beyond 100 pbw, the developing will be influenced.

IV. Solvent

The solvent may be the solvent provided in the above embodiment of colorant. During preparing the photosensitive resin composition, based on 100 pbw of the using amount of (A) pigment, the using amount of the solvent may be 200-3000 pbw, preferably 300-1800 pbw.

V. Additives

If necessary, photosensitive resin composition may further includes additives such as solidification accelerant, filling agent, macromolecular compound, leveling agent, wetting agent, defoaming agent, antioxidant, ultraviolet ray absorbent, and anticoagulant.

The solidification accelerant may be vinyl trimethoxy silane, vinyl triethoxy silane, vinyl tri(2-methoxy ethoxy)silane, N-(20 amino ethyl)-3-amino propyl methyl dimethoxy silane, N-(2-amino ethyl)-3 amino propyl trimethoxy silane, 3-amino propyl triethoxy silane, 3-expoxy propyl alcohol propyl trimethoxy silane, 3-expoxy propyl alcohol propyl methyl dimethoxy silane, 2-(3,4-expoxy cyclohexyl) ethyl trimethoxy silane, 3-chloropropyl methyl dimethoxy silane, 3-chloropropyl trimethoxy silane, 3-methyl propenyloxy propyl trimethoxy silane, 3-mercaptan group propyl trimethoxy silane, silane acrylic acid ester, silane diacrylic acid ester, silane triacrylic acid ester and so on;

The filling agent may be glass, alumina and so on.

The macromolecular compound may be polyvinyl alcohol, polyacrylic acid, polyethylene glycol monoalkyl ether, polyfluoro acrylic acid alkyl ester and so on;

The leveling agent, wetting agent, and defoaming agent may be surface active agent such as non-ionic, cationic, and anionic.

The antioxidant may be 2,2-sulpho-di(4-methyl-6-tert-butyl phenol), 2,6-di-tert-butyl phenol and so on.

The ultraviolet absorbent may be 2-(3-tert-butyl-5-methyl-2-hydroxyphenyl)-5-chlorobenzotriazole, and alkoxy benzophenone;

The anticoagulant may be polyacrylic acid sodium.

Besides the above additives, some expoxy resin, mercaptan, organic acid, and organic amine compound may be added.

The expoxy resin may be expoxy ethane, phenyl expoxy ethane; diphenolA-type expoxy resin such as commercial Epikote 828, Epikote 1001, Epikote 1002, Epikote 1004 (Shell Epoxy Corporation); diphenolF-type expoxy resin such as Epikote 807, Epikote 4001, Epikote 4002, Epikote 4004 (Shell Epoxy Corporation); (benzene) phenolic aldehyde-type expoxy resin such as Epikote 152, Epikote 154, Epikote 157S65, Epikote 157S70 (Shell Epoxy Corporation), DEN-438, DEN-439, DEN-354, DEN-431 (Dow Chemistry Corporation); various expoxy resin (preferably, resin containing more than two expoxy groups) such as Epolead PB3600 (daicel Chemical Industry Corporation), NER-7406, NER-1302 (Nippon Kayaka Corporation).

The mercaptan may be 2-mercapto benzothiophene, 2-mercapto benzoxazole, 2-mercapto benzimidazole, 2,5-dimercapto-1,3,4-thiadiazole, 2-mercapto-2,5-dimethylamino pyridine and so on.

The organic acid compound may be an fatty mono-carboxylic acid such as formic acid, acetic acid, propionic acid, butanoic acid, and caproic acid; fatty dicarboxylic acid such as oxalic acid, malonic acid, succinic acid, glutaric acid, adipic acid, suberic acid, itaconic acid, citraconic acid, maleic acid, and fumaric acid; fatty tricarboxylic acid such as propyl tricarboxylic acid, and propenyl tricarboxylic acid; aromatic carboxylic acid such as benzoic acid, benzoic acid, o-phthalic acid, m-phthalic acid, p-phthalic acid, trimesic acid, and mellophanic acid; phenyl acetic acid, hydrocinnamic acid, etc.

The organic amine compound may be normal propyl amine, isopropyl amine, normal butyl amine, isobutyl amine, tert-butyl amine, normal amyl amine, methyl ethyl amine, diethyl amine, methyl propyl amine, ethyl propyl amine, dinormal butyl amine, dimethyl ethyl amine, triethylamine, dimethyl propyl amine, 2-amino ethanol, 3-amino-1-propyl alcohol, 1-amino-2-propyl alcohol, diethanol amine, diisopropyl alcohol amine, triethanol amine, 2-amino butanoic acid, 3-amino butanoic acid, aniline, o-methylaniline, o-aminophenol, m-amino phenol, p-amino phenol, etc.

During preparing the photosensitive resin composition, one or more of the above additives may be mixed for use. Based on 100 pbw of pigment, the total using amount of the additives may be less than 30 pbw, preferably less than 20 pbw.

### Embodiment of Method

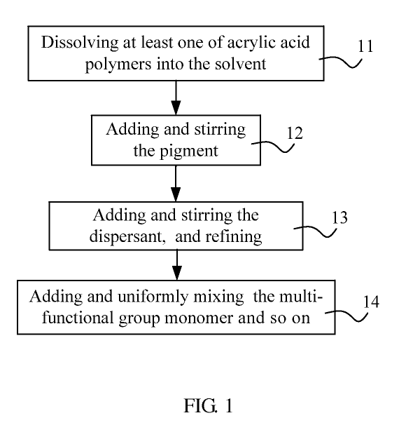

FIG. 1 is a flowchart illustrating the embodiment of method for preparing the photosensitive resin composition in the above embodiment of composition in accordance to the present invention. The method includes the following steps:

Step 11 is to dissolve at least one of the above acrylic acid polymers into the solvent. The acrylic acid polymer has been explained in detail in the above embodiment of colorant with an acid value greater than 20 mgKOH/g and containing the aromatic group. In this step, the acrylic acid polymer in the dispersant or in the dispersion resin shall be added into the solvent before adding the pigment so as to cover pigment particles firstly. During the process of wetting and refining the pigment, the solvent may be added at any time for diluting.

Step 12 is to add the pigment into the solution in which at least one kind of acrylic acid polymer is dissolved, stir to wet the pigment.

Step 13 is to add the dispersant, stir and refine to obtain the colorant. In order to obtain pigment particles with small particle diameters and distributed uniformly, a sand mill is preferably used to perform refining. Before the sand mill performs the refining, a mulser may be used to sufficiently wet the pigment preferably by stirring for 20-90 min at a speed of 2000-5000 rpm. The dispersant or dispersion resin used together with the acrylic acid polymer may be added before or after adding the pigment.

Step 14 is to add the multi-functional group monomer or a combination of the multi-functional group monomer and the mono-functional group monomer, optical initiator, and solvent; and mixing uniformly to obtain the photosensitive resin composition.

In the present embodiment, when it is needed to add additives, the additives can be added at any time, the viscosity of the photosensitive resin composition is preferably 1-50 cp, more preferably is 2-10 cp, and most preferably is 3-7 cp.

In order to make the present invention clearer, it is explained by comparing the embodiments and comparison examples.

Supposedly, the procedure of polymerizing to obtain the acrylic acid polymer includes: adding methyl acrylic acid 60 g, methyl acrylic acid methyl ester 21 g, methyl acrylic acid butyl ester 59 g, methyl acrylic acid benzyl ester 260 g, and solvent including propylene glycol monomethyl ether acetate (PMA) 600 g and dodecyl mercaptan Ig into a 2000mL 4-mouth flask, heating to 85° C. under protection of nitrogen, and keeping this temperature until the reaction finishes; finishing dripping the solution of the initiator NN di-isobutyl nitrile within half an hour, additionally dripping a little of initiator after polymerizing for 3 hours until total initiator 24 g is added, reacting for 6 hours, and then obtaining acrylic acid polymer by sedimentation or volatilizing all solvent.

It is supposed that the process of synthesizing the alkali-soluble resin is the same as the above process of obtaining the acrylic acid polymer, only with difference that the monomer is replaced by methyl acrylic acid 80 g, methyl acrylic acid methyl ester 20 g, methyl acrylic acid butyl ester 30 g, methyl acrylic acid ethoxyl ester 30 g, and methyl acrylic acid benzyl ester 240 g.

The process of preparing the photosensitive resin composition (also referred to embodiment 1 of preparing method hereafter) may include: dissolving the acrylic acid polymer 70 g and DisperBYK-2000 (solid contents40%) 50 g obtained by polymerizing into the propylene glycol monomethyl ether acetate 360 g, adding C.I. pigment red 254 120 g, stirring at a speed of 3000 rpm for 1 hour for fully wetting, and preliminarily dispersing to obtain preliminary dispersion liquid; adding solvent propylene glycol monomethyl ether acetate 200 into the preliminary dispersion liquid, stirring at a speed of 1000 rpm for 5 minutes, pouring into a sand mill, sand milling for 1 hour to obtain pigment refine dispersion liquid (i.e., the colorant); adding the above synthesized alkali-soluble resin 55 g, dipentaerythritol hexaacrylic acid ester 80 g, 2-benzyl-2-2dimethylamino-1-(4-morpholino phenyl)-1-butanone 30 g, (benzene) phenolic aldehyde type expoxy resin (DEN 438) 5 g, solvent propylene glycol monomethyl ether acetate 230 g into pigment refine dispersion liquid, stirring and uniformly mixing so as to obtain the photosensitive resin composition used for the color filter. The DisperBYK-2000 may be replaced by DisperBYK-2001 (solid contents 46%) or DisperBYK-161 (solid contents 30%). In order to facilitate explanation, the preparing process when the DisperBYK-2000 is replaced by the DisperBYK-2001 is referred to embodiment 2 of preparing method. The preparing process when the DisperBYK-2000 is replaced by the DisperBYK-161 is referred to embodiment 3 of preparing method.

Alternatively, the process of preparing the photosensitive resin composition (also referred to embodiment 4 of preparing method hereafter) may include: dissolving the acrylic acid polymer 70 g obtained by polymerizing into propylene glycol monomethyl ether acetate 360 g, adding C.I. pigment red 254 120 g, stirring at a speed of 300 rpm for half an hour to be fully wetting, and preliminarily dispersing; adding DisperBYK-2000 (solid contents40%) 50 g, stirring at a speed of 300 rpm for half an hour, pre-dispersing to obtain preliminary pre-dispersion liquid, adding solvent propylene glycol monomethyl ether acetate 200 g into the above preliminary pre-dispersion liquid, stirring at a speed of 1000 rpm for 5 minutes, pouring into a sand mill, sand milling for 1 hour to obtain pigment refine dispersion liquid; and stirring and uniformly mixing the alkali-soluble resin 55 g, dipentaerythritol hexaacrylic acid ester 80 g, 2-benzyl -2-2dimethylamino-1-(4-morpholino phenyl)-1-butanone 30 g, (benzene) phenolic aldehyde type expoxy resin (DEN 438) 5 g, solvent propylene glycol monomethyl ether acetate 230 g prepared in the synthesis example 2 so as to obtain the photosensitive resin composition used for the color filter.

### COMPARISON EXAMPLE 1

The acrylic acid polymer 70 g and DisperBYK-2000 (solid contents40%) 50 g in the above embodiment 1 of preparing method is replaced by DisperBYK-2000 (solid contents 40%) 75 g to prepare the photosensitive resin composition.

### COMPARISON EXAMPLE 2

The acrylic acid polymer 70 g and DisperBYK-2000 (solid contents40%) 50 g in the above embodiment 1 of preparing method is replaced by acrylic acid polymer 70 g to prepare the photosensitive resin composition.

### COMPARISON EXAMPLE 3

The adding order of the acrylic acid polymer 70 g and DisperBYK-2000 (solid contents 40%) 50 g in the above embodiment 1 of the preparing method is reversed, that is, the photosensitive resin composition is prepared by the following steps that the DisperBYK-2000 is firstly added and is stirred with the C.I. pigment red 254 for half an hour, and then acrylic acid polymer 70 g is added.

The photosensitive resin composition prepared in the embodiment 1-4 of the preparing method is compared with the photosensitive resin composition prepared in the comparison example 1-3, the comparison result is shown in Table 1.

TABLE 1

| | | | Developing |
|---|---|---|---|
| | Dispersion Ability | Stability | Performance |
| Embodiment 1 | Good | Good | Good |
| Embodiment 2 | Good | Good | Good |
| Embodiment 3 | Good | Good | Good |
| Embodiment 4 | Good | Good | Good |
| Comparison | Common | Bad | Bad |
| Example 1 | | | |
| Comparison | Bad | Common | Bad |
| Example 2 | | | |
| Comparison | Bad | Common | Common |
| Example 3 | | | |

In Table 1, the dispersion ability when a viscosity is less than 10 centipois and a particle diameter is less than 150 nm is evaluated to be good. The evaluation of the stability takes viscosity and particle size as evaluation parameters. The photosensitive resin composition prepared in the above embodiments and comparison examples is preserved in dark under room temperature for 4 weeks, and then the stability when changes of both the viscosity and the particle size less than 10% is evaluated to be good. The developing performance is obtained when the photosensitive resin composition is used to prepare the color filter. After exposure developing, the developing performance when the pattern's edge is clear and the non-exposure area has no residue left is evaluated to be good.

It can be seen from examples and comparison examples that the acrylic acid polymer can improve pigment refine stability of the colorant and may use many kinds of dispersion resin to disperse pigment particles. Therefore, especially to some pigment prepared to be colorant which is difficult to be stable such as C.I. pigment red 254, under synergistic action of the acrylic acid polymer and other dispersant or dispersion resin, the dispersion stability of the photosensitive resin composition is greatly improved. Besides, since the acid value of the acrylic acid polymer is greater than 20 mgKOH/g, contents of the colorant in the photosensitive resin composition almost have no influence on the developing performance so as to basically maintain the concentration of the alkali-soluble resin under the circumstance of increase of the colorant in the photosensitive resin composition. Thereby, comparing with the existing technique, the developing performance of the photosensitive resin composition in the above embodiment is greatly improved.

### Embodiment of Color Filter

The color filter may include a substrate which is provided with a pattern formed by any photosensitive resin composition provided in the above embodiment of composition.

The method for preparing the color filter at least includes the following steps:

Any photosensitive resin composition provided in the above embodiment of composition is coated onto the substrate;

The substrate after coating is irradiated by radioactive rays;

The substrate after exposure is putted into the developing solution for developing; and

The substrate after developing is post baked.

In the step of coating any photosensitive resin composition provided in the above embodiment of composition onto the substrate, the substrate may be coated by the photosensitive resin composition by means of spin coating, split coating, or a combination of the spin coating and the split coating. After coating, a process of preliminary baking is performed to volatilize the solvent and obtain a membrane layer. The condition of the preliminary baking is preferably 70-120° C., and about 2-5 min. The thickness of the membrane after the preliminary baking is preferably 0.2-4.0 μm.

The used substrate may be glass, silicon, polycarbonate, polyester, aromatic polyamide, polyimide, polyether sulphone, etc. If necessary, before coating, the substrate may perform suitable pre-treatment such as washing, plasma treatment, and ultraviolet ray treatment.

Through the above treatment, a black matrix (BM) is form on the substrate for separating sub-pixels.

The substrate after exposure may be put in the developing solution for developing, that is, the substrate obtained through the above treatment is irradiated by radioactive rays. The radioactive rays may preferably be g-line, h-line, or i-line ultraviolet rays. Normally, a mask is disposed between the light source and the substrate. The exposure amount of radioactive rays may preferably be about 10-10,00 mJ/cm².

The step of putting the substrate after exposure into the developing solution for developing includes: developing the irradiated substrate by developing solution, and removing a non-exposure area by dissolving to form pattern. The developing solution may be alkali solution, and preferably is aqueous solution of sodium carbonate, sodium bicarbonate, potassium carbonate, potassium bicarbonate, sodium hydroxide, potassium hydroxide, ammonia, ethylamine, diethylamine, pyrrole, tetramethyl ammonium hydroxyl oxide, choline, 1,8-diazabicyclo-[5.4.0]-7-undecene, or 1,5-diazabicyclo-[4.3.0]-5-nonene. Water-soluble organic solvent (such as methanol, and ethanol) and surface active agent may further be added. The concentration of the developing solution is preferably 0.001-5wt %. The time of developing is preferably 5-300 s. After developing, deionized water may be used for washing and nitrogen may be used for drying.

The substrate after developing is post baked. The substrate is mainly post baked for about 15-90 minutes under 180° C.-250° C.

By the above steps, the red phototonus resin composition, the green phototonus resin composition, and the blue phototonus resin composition may form a red pixel group, a green pixel group, and a blue pixel group onto the substrate respectively, and may further perform indium tin oxides (ITO) coating on pixels to form a color filter used for an LCD.

In the above embodiment of color filter and preparing method of color filter, the patterns on the color filter are formed by the photosensitive resin composition with high dispersion stability and developing performance so as to greatly improve the transmissivity, color purity and contrast.

### Embodiment of LCD Device

The LCD device may include a backlight, a thin film transistor (TFT) array substrate, a liquid crystal layer and a color filter. The color filter may be any color filter provided in the above embodiment. The liquid crystal layer transmits light of backlight to the color filter under control of the TFT array substrate. The color filter provides hue for the projected light. At this time, a color display image is formed on the screen of the LCD device.

The LCD device in the present embodiment greatly improves display effect of color images by the color filter with high transmissivity, high color purity, and high contrast.

Finally, it should be understood that the above embodiments are only used to explain, but not to limit the technical solution of the present invention. In despite of the detailed description of the present invention with referring to above preferred embodiments, it should be understood that various modifications, changes or equivalent replacements can be made by those skilled in the art without departing from the scope of the present invention and covered in the claims of the present invention.

What is claimed is:

1. A colorant, comprising a pigment, a dispersant or a dispersion resin, and a solvent, wherein the colorant further comprises at least one kind of acrylic acid polymer adapted to be mixed with the dispersant or dispersion resin by the solvent for dispersing and stabilizing the pigment; the acrylic acid polymer has an acid value greater than 20 mgKOH/g and contains aromatic group.

2. The colorant according to claim 1, wherein the aromatic group is benzene ring.

3. The colorant according to claim 1, wherein based on 100 pbw of the pigment, the acrylic acid polymer is 1-200 pbw.

4. The colorant according to claim 1, wherein based on 100 pbw of the acrylic acid polymer, the dispersant or dispersion resin is 1-300 pbw.

5. The colorant according to claim 1, wherein the acrylic acid polymer is any one or any combination of: copolymer of acrylic acid, copolymer of acrylic acid ester, copolymer of styrene, copolymer of maleic acid, and copolymer of vinyl group compound.

6. The colorant according to claim 1, wherein a weight-average molecular weight of the acrylic acid polymer is 2000-400000.

7. The colorant according to claim 1, wherein the acrylic acid polymer is polymerized by unsaturated monomer having aromatic functional group and copolymerisable monomer, and the copolymerisable monomer at least comprises one kind of unsaturated monomer which can be copolymerized with the unsaturated monomer having aromatic functional group and which contains carboxylic acid group or anhydride group.

8. The colorant according to claim 7, wherein the pbw proportion of the unsaturated monomer having the aromatic functional group to the copolymerisable monomer is 20: 80-90:10.

9. The colorant according to claim 8, wherein in the 10-80 pbw of the copolymerisable monomer, the unsaturated monomer which can be copolymerized with the unsaturated monomer and which contains the carboxylic acid group or anhydride group is 5-40 pbw.

10. A photosensitive resin composition, comprising a colorant of claim 1, a multi-functional group monomer or a combination of a multi-functional group monomer and a mono-functional group monomer, an optical initiator, and a solvent, wherein the colorant is mixed together with the multi-functional group monomer or the combination of the multi-functional group monomer and the mono-functional group monomer, the optical initiator, and the solvent.

11. The photosensitive resin composition according to claim 10, wherein the photosensitive resin composition further comprises alkali-soluble resin; and based on 100 pbw of the pigment in the colorant, the alkali-soluble resin is 1-120 pbw.

12. The photosensitive resin composition according to claim 10, wherein based on 100 pbw of the pigment in the colorant, the multi-functional group monomer is 10-500 pbw.

13. The photosensitive resin composition according to claim 10, wherein, in the combination of the multi-functional group monomer and the mono-functional group monomer, based on 100 pbw of the multi-functional group monomer, the mono-functional group monomer is 0-40 pbw.

14. The photosensitive resin composition according to claim 13, wherein, based on 100 pbw of the multi-functional group monomer or the combination of the multi-functional group monomer and the mono-functional group monomer, the optical initiator is 0.01-100 pbw.

15. The photosensitive resin composition according to claim 10, wherein based on 100 pbw of the pigment in the colorant, the solvent is 200-3000 pbw.

16. The photosensitive resin composition according to claim 10, wherein the photosensitive resin composition further comprises additives; and based on 100 pbw of the pigment in the colorant, the amount of the additives is less than 30 pbw.

17. A color filter, comprising a substrate, wherein the substrate is provided with a pattern formed by the photosensitive resin composition in the claim 10.

18. An LCD device, comprising a liquid crystal layer and a color filter of claim 17, wherein the color filter is disposed over the liquid crystal layer.

19. A method for preparing the photosensitive resin composition of claim 10, comprising:
dissolving at least one kind of the acrylic acid polymer into solvent, wherein the acrylic acid polymer has an acid value greater than 20 mgKOH/g and contains aromatic group;
adding the pigment into solution in which at least one kind of acrylic acid polymer is dissolved, and stirring;
adding the dispersant or dispersion resin, stirring, and refining; and
adding the multi-functional group monomer or combination of multi-functional group monomer and mono-functional group monomer, optical initiator, and solvent.
